(19) United States
(12) Patent Application Publication
(10) Pub. No.: US 2009/0200467 A1
(43) Pub. Date: Aug. 13, 2009

(54) Automatic image-based volumetric detection of an object in a space

(76) Inventors: Paul C. Gray, Garland, TX (US); Giuseppe Di Stefano, Keller, TX (US); Ronald Bruce Blair, Flower Mound, TX (US)

Correspondence Address: Law Offices of Scott B. Stahl;Suite 200, 555 Republic Drive, Plano, TX, 75074, US

(21) Appl. No.: 12/069,653

(22) Filed: Feb. 12, 2008

(51) Int. Cl. H01L 25/00; H01L 27/00

(52) U.S. Cl. 250/332; 250/208.1

(57) ABSTRACT

Automatic image-based volumetric detection of an object in a space is achieved based on a combinational characteristic produced by combining a first characteristic of a reference image associated with the space when empty, and second characteristic of a detection image associated with the space at a time when object detection is active. The combinational characteristic is independent of relative image intensity between the reference image and the detection image. The object detection operation is thus provided with a degree of independence relative to the respective illumination conditions during capture of the reference and detection images.

### FIELD OF THE INVENTION

The invention relates generally to image processing and, more particularly, to the use of image processing to support automatic volumetric detection of an object in a space.

### BACKGROUND OF THE INVENTION

The ability to detect the presence of an object in a space or volume automatically (i.e., without human participation in the detection) has many applications, such as safety, security, manufacturing, quality assurance, etc. According to conventional detection strategies, images associated with the space of interest are used. The images are produced by illuminating the space with electromagnetic radiation (e.g., visible light, infrared, etc.), and capturing the reflection activity. For example, a digital camera arrangement can be used to capture images produced by the reflection of the illuminating radiation. A reference image is captured when the space is free of the object, and a detection image is captured when it is desired to detect whether the object is present in the space. The decision regarding the presence or absence of the object depends on a difference between an image intensity characteristic of the reference image and an image intensity characteristic of the detection image. If these image intensity characteristics (typically represented by pixel values) differ enough from one another, then the object is considered present in the space.

However, if the respective illumination intensities used to produce the reference and detection images differ enough, then the respectively corresponding image intensity characteristics may also differ enough to produce a positive object detection decision, even when the object is in fact absent. Thus, acceptable detection decision accuracy can be achieved, but with the constraint that suitably similar illumination intensities are used to produce both the reference and detection images.

It is desirable in view of the foregoing to provide for automatic image-based object detection with robust detection decision accuracy.

### BRIEF DESCRIPTION OF THE DRAWINGS

FIG. 1 diagrammatically illustrates a system that performs object detection according to exemplary embodiments of the invention.

FIG. 2 diagrammatically illustrates a portion of FIG. 1 according to exemplary embodiments of the invention.

FIG. 3 conceptually illustrates the use of a guard region of pixels in a reference image according to exemplary embodiments of the invention.

FIG. 4 illustrates a portion of FIG. 1 according to exemplary embodiments of the invention.

FIGS. 5-8 illustrate operations that can be performed according to exemplary embodiments of the invention.

### DETAILED DESCRIPTION

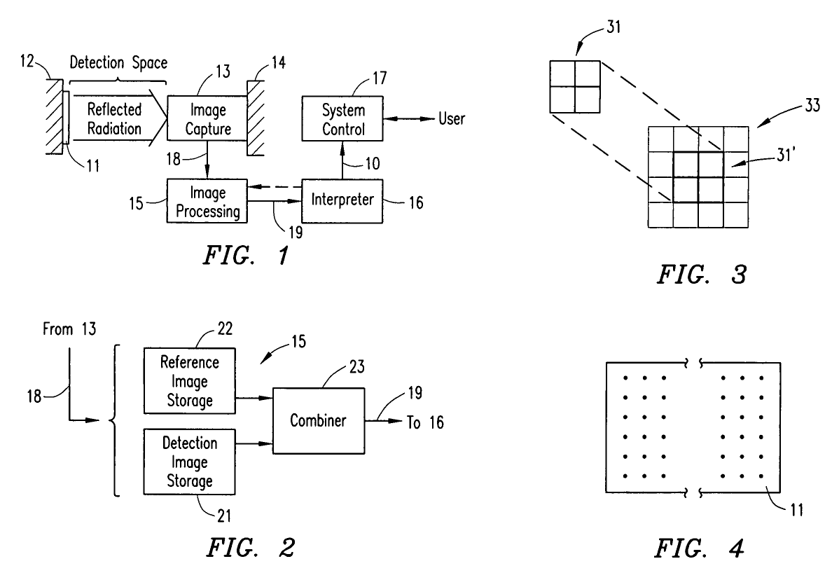

FIG. 1 diagrammatically illustrates a system for monitoring whether an object is present in a given three-dimensional space or volume. A detection space is defined between a reflecting surface 11 and an image capture arrangement 13 that bound respectively opposite ends of the detection space. The surface 11 is provided on a structure 12, and the image capture arrangement 13 is provided on a structure 14. The image capture arrangement 13 is oriented in generally opposed relationship with, and across the detection space from, the surface 11. The surface 11 has provided thereon a reflecting pattern that reflects incident electromagnetic radiation in accordance with that pattern. The reflected radiation passes through the detection space and is received by the image capture arrangement 13, which captures an image of the pattern. In some embodiments, the image capture arrangement 13 includes one or more digital cameras or other suitable image capture device(s). In some embodiments, the image capture arrangement 13 includes a conventional source of electromagnetic radiation that illuminates, and is reflected by, the surface 11. In various embodiments, the electromagnetic radiation includes one or both of near-infrared radiation (e.g., 1000-1100 nanometer wavelengths) and visible light radiation.

When the detection space is free of objects, the reflection of the illumination from the surface 11 will be captured at 13 as an image of the pattern on the surface 11. This image can then be used as a reference image for object detection processing. At a time when it is desired to determine whether an object is present in the detection space, a further image is captured at 13. This further image is referred to herein as a detection image. If no object is present in the detection space, then the detection image can be expected to match the reference image, exhibiting the image pattern produced by reflection of illumination from the pattern on the surface 11. If an object is present in the detection space, then the detection image will differ from the reference image due to the presence of the object in the reflection path. This difference between the detection image and the reference image can be detected according to exemplary embodiments of the invention, whereby the presence of the object is objected.

If an object is present in the detection space, the detection image will differ from the reference image regardless of how thin the object is as measured in the direction extending between the surface 11 and the image capture arrangement 13, and regardless of where the object is located between the surface 11 and the image capture arrangement 13. For example, at the time that the detection image is captured, if a razor blade is positioned in the detection space midway between the surface 11 and the image capture arrangement 13, and is oriented generally parallel to the surface 11, the presence of the razor blade in the detection space can be detected.

An image processor 15 coupled to the image capture arrangement 13 receives the captured reference image information and the captured detection image information at 18, and processes this image information to produce detection information at 19. In some embodiments, the image processor is located remotely from the image capture arrangement 13. An interpreter 16 receives the detection information at 19 and uses that information to decide whether an object is present in the detection space. In some embodiments, the interpreter 16 is located remotely from the image processor 15. If the interpreter 16 decides that an object is present, this decision can be forwarded at 10 to a system controller 17 that initiates an appropriate reaction to the decision. In some embodiments, the system controller 17 is located remotely from the interpreter 16.

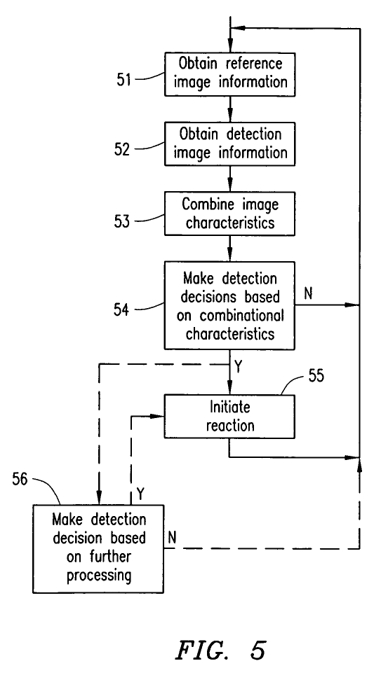

FIG. 2 diagrammatically illustrates the image processor 15 in more detail according to exemplary embodiments of the invention. The reference image information and detection image information received at 18 are respectively stored in reference image storage 22 and detection image storage 21. A combiner 23 combines characteristics respectively associated with the reference and detection images, thereby to produce the detection information at 19 as combinational characteristics derived from the characteristics of the respective images. In some embodiments, the stored image information includes a reference array of pixel values associated with the reference image and a detection array of pixel values associated with the detection image. These pixel values provide the image characteristics that are combined by the combiner 23.

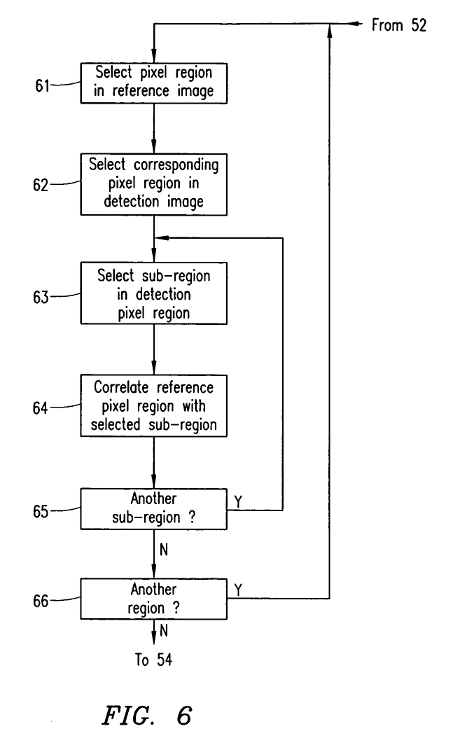

According to exemplary embodiments of the invention, the detection information produced by the combiner 23 is independent of the relative image intensity between the reference and detection images. This advantageously provides the detection information with a degree of independence relative to the respective illumination conditions during capture of the reference and detection images. The combiner 23 performs a two-dimensional similarity analysis with respect to the pixel values of the reference and detection images. In some embodiments, the two-dimensional similarity analysis includes a two-dimensional normalized correlation operation with respect to the pixel values of the reference and detection images. The combiner 23 selects from the reference pixel array an M×N pixel region (where M and N are integers), for example, a 2×2 pixel region such as shown at 31 in FIG. 3 (M=N=2 in the example of FIG. 3). The combiner 23 also selects the corresponding N×N pixel region from the detection pixel array, for example, a 2×2 pixel region 31′ as shown in FIG. 3. Each pixel region 31 selected from the reference pixel array is correlated with the corresponding pixel region 31′ from the detection pixel array. The combinational characteristics contained in the detection information at 19 are the results of these normalized correlation operations, i.e., correlation values. These correlation values are independent of the relative image intensity between the reference and detection images. The normalized correlation operations serve to compare the reference and detection images for determining whether the detection image includes any anomalies that “disrupt” the pattern associated with the reference image. If a given correlation value exceeds a threshold, this indicates that the pattern on the surface 11 has not been disrupted by the presence of an object. If the correlation value is below the threshold, this indicates that the pattern is disrupted by an anomaly associated with the presence of an object. The threshold value can be set as necessary for the desired sensitivity of the detection operation. A suitable threshold value for use with a given set of operating conditions (e.g., the pattern on the surface 11, the capabilities of the image capture arrangement 13, and the desired object detection sensitivity) can be determined, for example, by empirical testing under that set of operating conditions.

In some embodiments, tolerance considerations such as camera jitter and other factors are addressed by, for example, extending the correlation operation beyond the corresponding pixel region of the detection array, into a surrounding region of guard pixels, such as the 12 pixels surrounding the 2×2 region 31′ in FIG. 3. In this example, the pixel region 31′ in the detection image array, which ideally corresponds to the pixel region 31 from the reference image array, is a 2×2 sub-region of pixels within a selected 4×4 pixel region 33. Note that there are nine 2×2 sub-regions within the 4×4 pixel region 33, so nine correlation operations will be performed for each 2×2 region of the reference pixel array. Some embodiments correlate the reference pixel region 31 with all nine 2×2 sub-regions within the detection pixel region 33, and select the maximum of the resulting correlation values for comparison to the threshold. In general, each selected reference pixel region is an M×N region, and the corresponding selected detection pixel region is an (M+G)×(N+G) region (M=N=G=2 in the example of FIG. 3) composed of K M×N sub-regions (K=9 in the example of FIG. 3).

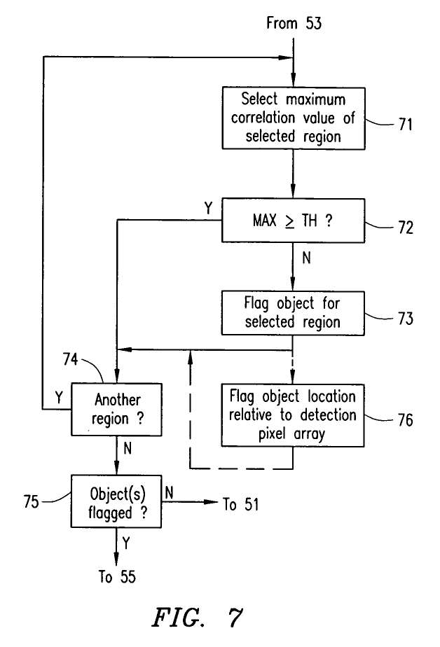

FIG. 4 shows one example of a reflecting pattern that can be provided on the surface 11, as viewed from the perspective of the image capture arrangement 13 in FIG. 1. This particular pattern can be used where the illuminating radiation is visible light. As shown, the pattern consists of a rectangular grid of dark (e.g., black) circular dots on a light (e.g., white) contrasting background. The dots within each row of the grid are equally spaced from one another, the rows of the grid are equally spaced from one another, and the spacing between the dots in the rows is the same as the spacing between the rows.

Various embodiments use various reflecting patterns on the surface 11. In general, patterns that have characteristics such as described below tend to provide acceptable performance. The pattern should preferably produce, in any given pixel region (such as shown at 31 in FIG. 3) within the reference image, one or more pixels that contrast with one or more other pixels in that pixel region. The amount of contrast between two pixels is the difference between their respective pixel values, so the highest possible contrast between any two pixels is the difference between the maximum possible pixel value and the minimum possible pixel value. In some embodiments, a contrasting pixel pair (of which there is one or more within each pixel region) is defined as a pair of pixels whose respective values differ from one another by at least a nominal level of contrast. Various patterns in various embodiments produce in the corresponding reference images various numbers of contrasting pixel pairs. In general, for given image capture and image processing conditions, object detection sensitivity can be expected to improve with an increase in the value of one or both of the following reference image parameters: (1) the number of contrasting pixel pairs within a pixel region; and/or (2) the nominal level of contrast.

Acceptable patterns for use under given image capture and image processing conditions can be determined, for example, by empirical testing of object detection performance using different patterns under the given image capture and image processing conditions. Patterns that produce acceptable object detection performance are acceptable patterns. Acceptable values for the aforementioned reference image parameters can then be determined directly, by analyzing the pixel values within the pixel regions of reference images produced by acceptable patterns. The pixel values of reference images produced by further patterns can be examined in view of the acceptable reference image parameter values to determine whether those further patterns will provide acceptable objection detection performance. In some embodiments, even randomly produced patterns can provide acceptable object detection performance.

As a specific example, some embodiments (e.g., some passenger security revolving door embodiments as described in more detail hereinbelow) use a pattern of the same general type described above with respect to FIG. 4, and wherein each of the circular dots has a diameter of 0.125 inches, wherein the density of the dots is four dots per square inch, and wherein the image capture arrangement 13 and image processor 15 use a pixel density of 256 pixels per square inch.

In some embodiments, the interpreter 16 of FIG. 1 also receives the detection pixel array from the image processor 15, and forwards it to the system controller 17 together with an indication of the pixel region(s) therein that have triggered a positive object detection decision. The system controller 17 then uses this information to produce a visual display of the detection image with the location(s) of any detected object(s) visually flagged therein. This visual display enhances the ability of a user (e.g., security personnel or inspection personnel) of the system controller 17 to determine an appropriate reaction to, and/or identify, the detected object.

Some embodiments provide for automatically updating the reference image. The interpreter 16 informs the image processor 15 (see broken line in FIG. 1) if no objects are detected in the current detection image, and the image processor automatically uses the current detection image information (e.g., the current detection pixel array) as the next reference image information (e.g., the next reference pixel array).

As will be apparent to workers in the art, the image processor 15, interpreter 16 and system controller 17 can be readily implemented using various types of commercially available data processing resources.

As an example of a specific application, in some embodiments, the structures 14 and 12 of FIG. 1 are the ceiling and floor, respectively, of a passenger security revolving door apparatus such as used in airports. (Doors of this general type are commercially available, for example, from Blasi Automatic Doors). In such passenger security revolving door embodiments, the detection space of FIG. 1 corresponds to the interior chamber (particularly on the non-secure side) of the revolving door. The surface 11 can be provided as a floor covering such as vinyl. If the interpreter 16 informs the system controller 17 that an object has been detected, security personnel (see also the user in FIG. 1) monitoring the system controller 17 can react appropriately, for example, by dispatching an investigator to the site of the door.

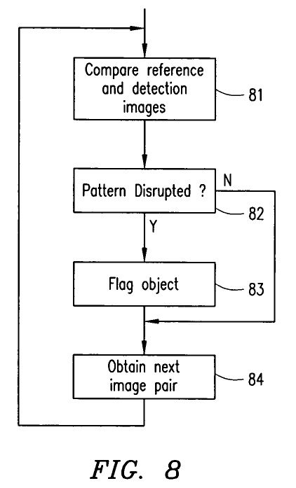

FIGS. 5-8 illustrate examples of operations described above with respect to FIGS. 1-3. Referring to FIG. 5, reference image information is obtained at 51, and detection image information is obtained at 52. Thereafter, at 53, characteristics of the reference image are combined with characteristics of the detection image to produce combinational characteristics. At 54, object detection decisions are made based on the combinational characteristics. If there are no affirmative object detection decisions at 54, then operations return to 51. If at least one affirmative object detection decision is taken at 54, then an appropriate reaction at the system control level is initiated at 55.

FIG. 6 illustrates an example of combining reference image characteristics with detection image characteristics (see also 53 in FIG. 5) according to exemplary embodiments of the invention. In some embodiments, the image processor 15 of FIG. 1 is capable of performing the operations shown in FIG. 6. At 61, a pixel region (such as 31 in FIG. 3) in the reference image is selected. At 62, a corresponding pixel region (such as 33 in FIG. 3) in the detection image is selected. At 63, a sub-region (such as 31′ in FIG. 3) of the selected pixel region in the detection image is selected. At 64, a correlation operation is performed with respect to the selected region of the reference image and the selected sub-region in the detection image. As shown at 65, the operations at 63 and 64 are repeated until all sub-regions within the selected pixel region of the detection image have been correlated. Then, as shown at 66, the operations at 61-65 are repeated until all pixel regions in the reference image have been correlated, after which operations return to 54 in FIG. 5.

FIG. 7 illustrates an example of making detection decisions (see also 54 in FIG. 5) according to exemplary embodiments of the invention. In some embodiments, the interpreter 16 of FIG. 1 is capable of performing the operations shown in FIG. 7. At 71, the maximum correlation value among all sub-regions in the selected region of the detection pixel array is selected. At 72, if the maximum correlation value, MAX, is less than a threshold value, TH, then detection of an object is flagged at 73. Otherwise, no object is detected. The operations at 71-73 are repeated for all regions of the detection image, as shown at 74. After all regions have been considered, it is determined at 75 whether any objects have been flagged as present. If so, operations proceed to 55 in FIG. 5. If not, operations return to 51 in FIG. 5. FIG. 7 also illustrates (in broken line) the aforementioned capability, in some embodiments, of flagging the location(s) of any detected object(s) relative to the corresponding pixel regions in the detection pixel array, in order to permit visual display of the detection image with object locations visually flagged therein.

Some embodiments perform further analysis of the object detection results. Having already decided, for each pixel region, whether an object is present with respect to that region (see also FIG. 7), some embodiments apply conventional blob analysis and/or conventional pattern recognition to the object detection results associated with the respective pixel regions. The result of such further analysis can then be used to decide whether an object is present in the detection space. This further analysis is indicated by broken line at 56 in FIG. 5. Even though an object has been detected at 54 with respect to one or more pixel regions, a reaction at the system control level is not initiated at 55 unless the further analysis of the object detection results that were produced at 54 produces an affirmative object detection decision at 56. If the further analysis at 56 produces a negative object detection decision, then operations return to 51. The further analysis at 56 can be useful, for example, for avoiding false alarms and/or for detecting the presence of specific types of objects, for example, a knife or a razor blade present in the detection space in a passenger security revolving door embodiment.

FIG. 8 illustrates the aforementioned capability of detecting pattern disruptions according to exemplary embodiments of the invention. The reference and detection images are compared at 81 (e.g., by pixel correlation operations), after which it is determined at 82 (e.g., by evaluating the magnitude of pixel correlation values) whether the pattern in the reference image is disrupted in the detection image. If no pattern disruption is detected at 82, then the next reference image/detection image pair is obtained at 84, after which operations return to 81. If a pattern disruption is detected at 82, then detection of an object is flagged at 83, after which operations proceed to 84.

Although exemplary embodiments of the invention have been described above in detail, this does not limit the scope of the invention, which can be practiced in a variety of embodiments.

What is claimed is:

1. A method of detecting whether an object that reflects electromagnetic radiation is present in a space, comprising:
using electromagnetic radiation to produce a reference image associated with said space at a time when said space is free of the object;
using electromagnetic radiation to produce a detection image associated with said space at a time when detection of whether the object is present in said space is desired;
combining a first characteristic associated with said reference image and a second characteristic associated with said detection image to produce a combinational characteristic that is independent of relative image intensity between said reference image and said detection image; and
deciding, based on said combinational characteristic, whether the object is present in said space.

2. The method of claim 1, wherein said first and second characteristics respectively include first and second sets of pixel values, and said combinational characteristic includes a combinational value produced by said combining.

3. The method of claim 2, wherein said combining includes correlating said first and second sets of pixel values, and said combinational value is a correlation value.

4. The method of claim 2, wherein said combining includes combining said first set of pixel values with a plurality of sets of pixel values associated with said reference image to produce a plurality of combinational values that respectively correspond to said plurality of sets of pixel values.

5. The method of claim 4, wherein said deciding includes comparing at least one of said combinational values to a remainder of said combinational values.

6. The method of claim 5, wherein said deciding includes comparing said at least one combinational value to a threshold value.

7. The method of claim 1, wherein said electromagnetic radiation includes one of visible light radiation and near-infrared radiation.

8. The method of claim 1, including providing in a visual display of said detection image an indication of where the object is located in said detection image.

9. A method of detecting whether an object that reflects electromagnetic radiation is present in a space, comprising:
at a time when said space is free of the object, receiving electromagnetic radiation reflected through said space from a surface that bounds said space and is adapted to reflect electromagnetic radiation in accordance with a predetermined pattern, thereby to produce a reference image of said predetermined pattern;
at a time when detection of whether the object is present in said space is desired, receiving electromagnetic radiation reflected through said space from at least a portion of said surface, thereby to produce a detection image;
comparing said reference image to said detection image to produce detection information indicative of whether said detection image exhibits a disruption of the predetermined pattern; and
based on said detection information, deciding whether the object is present in said space.

10. The method of claim 9, wherein said comparing includes combining a first set of pixel values associated with said detection image with a second set of pixel values associated with said reference image, and said detection information includes a combinational value produced by said combining.

11. The method of claim 10, wherein said combining includes combining said first set of pixel values with a plurality of sets of pixel values associated with said reference image, and said detection information includes a plurality of combinational values that are produced by said combining and respectively correspond to said plurality of pixel values.

12. The method of claim 11, wherein said deciding includes comparing at least one of said combinational values to a remainder of said combinational values.

13. The method of claim 12, wherein said deciding includes comparing said at least one combinational value to a threshold value.

14. The method of claim 10, wherein said combining includes correlating said first and second sets of pixels values, and said combination value is a correlation value.

15. The method of claim 8, including providing in a visual display of said detection image an indication of where the object is located in said detection image.

16. An apparatus for detecting whether an object that reflects electromagnetic radiation is present in a space, comprising:
an image capture arrangement configured to produce, in response to received electromagnetic radiation, a reference image that is associated with said space at a time when said space is free of the object, said image capture arrangement further configured to produce, in response to received electromagnetic radiation, a detection image that is associated with said space at a time when detection of whether the object is present in said space is desired;
an image processor coupled to said image capture arrangement and configured to combine a first characteristic associated with said reference image and a second characteristic associated with said detection image to produce a combinational characteristic that is independent of relative image intensity between said reference image and said detection image; and
an interpreter coupled to said image processor and configured to decide, based on said combinational characteristic, whether the object is present in said space.

17. The apparatus of claim 16, wherein said first and second characteristics respectively include first and second sets of pixel values, and said combinational characteristic includes a combinational value produced by combining said first and second sets of pixel values.

18. The apparatus of claim 17, wherein said image processor is configured to correlate said first and second sets of pixel values, and said combinational value is a correlation value.

19. An apparatus for detecting whether an object that reflects electromagnetic radiation is present in a space, comprising:
a surface that bounds said space and is adapted to reflect electromagnetic radiation in accordance with a predetermined pattern;
an image capture arrangement positioned to receive electromagnetic radiation reflected from said surface, said image capture arrangement configured to produce, at a time when said space is free of the object, a reference image of said predetermined pattern in response to electromagnetic radiation reflected through said space from said surface, said image capture arrangement further configured to produce, at a time when detection of whether the object is present in said space is desired, a detection image in response to electromagnetic radiation reflected through said space from at least a portion of said surface;
an image processor coupled to said image capture arrangement and configured to compare said reference image to said detection image to produce detection information indicative of whether said detection image exhibits a disruption of said predetermined pattern; and
an interpreter coupled to said image processor and configured to decide, based on said detection information, whether the object is present in said space.

20. The apparatus of claim 19, wherein said image processor is configured to combine a first set of pixel values associated with said detection image with a second set of pixel values associated with said reference image, and said detection information includes a combinational value produced by combining said first and second sets of pixel values.

21. The apparatus of claim 20, wherein said image processor is configured to correlate said first and second sets of pixels values, and said combination value is a correlation value.

22. The apparatus of claim 19, provided as a passenger security revolving door apparatus having a floor with said surface installed thereon, and having a ceiling with said image capture arrangement installed thereon.

23. A system for monitoring whether an object that reflects electromagnetic radiation is present in a space, comprising:
an image capture arrangement configured to produce, in response to received electromagnetic radiation, a reference image that is associated with said space at a time when said space is free of the object, said image capture arrangement further configured to produce, in response to received electromagnetic radiation, a detection image that is associated with said space at a time when detection of whether the object is present in said space is desired;
an image processor coupled to said image capture arrangement and configured to combine a first characteristic associated with said reference image and a second characteristic associated with said detection image to produce a combinational characteristic that is independent of relative image intensity between said reference image and said detection image;
an interpreter coupled to said image processor and configured to decide, based on said combinational characteristic, whether the object is present in said space; and
a controller coupled to said interpreter, said interpreter operable for providing an indication to said controller if said interpreter decides that the object is present in said space, said controller configured to initiate a reaction to said indication.

24. The system of claim 23, wherein said interpreter and said controller are cooperable to provide a visual display of said detection image that includes therein a visual indication of where the object is located in said space.

25. A system for monitoring whether an object that reflects electromagnetic radiation is present in a space, comprising:
a surface that bounds said space and is adapted to reflect electromagnetic radiation in accordance with a predetermined pattern;
an image capture arrangement positioned to receive electromagnetic radiation reflected from said surface, said image capture arrangement configured to produce, at a time when said space is free of the object, a reference image of said predetermined pattern in response to electromagnetic radiation reflected through said space from said surface, said image capture arrangement further configured to produce, at a time when detection of whether the object is present in said space is desired, a detection image in response to electromagnetic radiation reflected through said space from at least a portion of said surface;
an image processor coupled to said image capture arrangement and configured to compare said reference image to said detection image to produce detection information indicative of whether said detection image exhibits a disruption of said predetermined pattern;
an interpreter coupled to said image processor and configured to decide, based on said detection information, whether the object is present in said space; and
a controller coupled to said interpreter, said interpreter operable for providing to said controller an indication that the object is present in said space, said controller configured to initiate a reaction to said indication.

26. The system of claim 25, wherein said interpreter and said controller are cooperable to provide a visual display of said detection image that includes therein a visual indication of where the object is located in said space.

27. The system of claim 25, including a passenger security revolving door apparatus having a floor with said surface installed thereon, and having a ceiling with said image capture arrangement installed thereon.
